(19) United States
(12) Patent Application Publication
(10) Pub. No.: US 2021/0006233 A1
(43) Pub. Date: Jan. 7, 2021

(54) MULTIPLEXER AND FRONTEND MODULE COMPRISING A MULTIPLEXER

(71) Applicant: RF360 EUROPE GMBH, Munchen (DE)

(72) Inventor: Roeland HEIJNA, EB WELL (NL)

(21) Appl. No.: 16/977,763

(22) PCT Filed: Feb. 7, 2019
(86) PCT No.: PCT/EP2019/053044

§ 371 Date: Sep. 2, 2020

(30) Foreign Application Priority Data
Mar. 15, 2018 (DE) 10 2018 106 028.9

(51) Int. Cl. H03H 9/72; H03H 9/64; H03F 3/24; H04B 1/10; H04L 25/02; H04B 1/04

(52) U.S. Cl. CPC H03H 9/72; H03H 9/6483; H03F 3/245; H04B 1/1027; H04L 25/0278; H04B 2001/0408; H03F 2200/171; H03F 2200/294; H03F 2200/451; H04B 2001/1063; H04B 1/0475

(57) ABSTRACT

A multiplexer circuit with good isolation characteristics and a compensated frequency characteristic at the transmission side is presented. The multiplexer circuit has a reception filter notch circuit (RFNC) active at a frequency within a passband of a reception filter (RXF) and coupled between an input port and a transmission filter (TXF).

The present invention refers to a multiplexer that can be used in mobile communication systems and to frontend modules comprising such multiplexers.

In mobile communication devices communication between different participants takes place by exchanging RF signals. A frontend is the part of the corresponding communication device that receives signals are to be transmitted from an external circuit environment of the communication device and that submits received signals to an external circuit environment of the communication device. To that end transmission signals propagate in a transmission signal path and reception signals propagate in a reception signal path. To prevent the transmission signals from corrupting reception signals, the corresponding signal paths must be isolated from one another and the matrix element S2₂₁ of the transfer function is a measure for this isolation.

Further, transmission signals are received from a power amplifier and reception signals are submitted to a low noise amplifier. Usually the output port of a power amplifier has a very low impedance while other circuit components within the transmission signal path have a standard impedance such as 25Ω, 50Ω, 100Ω or 200Ω. Thus, what is additionally needed is an impedance matching network that matches the output impedance of the power amplifier to an input impedance, e.g. of a transmission filter within the transmission signal path.

However, generally the output impedance of the power amplifier, the input impedance of an impedance matching circuit, the output impedance of an impedance matching circuit and the input port of a transmission filter have a frequency dependence, the compensation of which further increases the complexity of the frontend module.

Further, the trend towards miniaturization calls for smaller components, which makes maintaining a certain degree of isolation difficult. Further, especially at low frequencies large capacitance values for impedance compensation are needed. However, large capacitance values are more difficult to establish in miniaturized frontend modules.

Thus, what is needed is a multiplexer that is compatible with the trend towards miniaturization, that can be manufactured in a cost-efficient manner and that allows handling of frequency dependencies in mobile communication systems and provides a good level of isolation.

To that end a multiplexer circuit and a frontend module comprising a multiplexer circuit according to the independent claims are provided. The dependent claims provide preferred embodiments.

The multiplexer circuit comprises an input port, a common port, an output port and a signal line. The signal line is arranged between the input port and the common port. Further, the multiplexer circuit comprises a transmission filter between the input port and the common port and a reception filter coupled to the output port. Further, the multiplexer circuit comprises a reception filter notch circuit coupled between the input port and the transmission filter. The reception filter has a passband. The reception filter notch circuit is active at a frequency within the passband of the reception filter.

The input port is provided to receive RF signals from an external circuit environment, e.g. a power amplifier of a mobile communication device of which the multiplexer circuit can be part. The output port is a port provided for submitting received RF signals to an external circuit environment. The common port can be a port where an antenna connection can be established. Further, the common port can be a port where the multiplexer circuit is electrically connected to other circuit elements, e.g. further multiplexer circuits of a mobile communication device. The signal line between the input port and the common port is provided to conduct RF signals from the input port to the common port. The transmission filter is provided to submit transmission signals to the common port and to filter other frequency components, i.e. to remove other frequency components unwanted at the common port. The reception filter is provided to isolate the output port from the common port for mainly every frequency component that should not be received at the output port. The reception filter is one important circuit element to establish a certain level of isolation.

The reception filter notch circuit, which is coupled between the input port and the transmission filter, is a second important circuit element that helps maintaining a certain level of isolation.

The present multiplexer circuit is special in that a circuit component, namely the reception filter notch circuit, which is active at a frequency within the passband of the reception filter, is arranged before the transmission filter. Such configuration allows fulfilling different requirements by a single component in an elegant manner: The reception filter notch circuit improves isolation between the transmission signal path and the reception signal path and simultaneously helps handling the frequency dependence of the circuit components in the transmission signal path. Especially for lower RF frequencies special circuit components are needed to handle the unwanted frequency dependencies. In the context of the present invention it was recognized that moving the corresponding circuit component from the reception side signal path of a multiplexer to the transmission side does not increase the total number of needed circuit components and does not increase the needed space or volume within the frontend module but simultaneously allows maintaining a good isolation level and a reduction of frequency dependencies.

To that end, the reception filter notch circuit can provide a notch in the transfer function of the transmission signal path in the corresponding frequency range, which is the working frequency range of the reception filter.

It is to be noted that the transmission filter and the reception filter are not necessarily two filters of a duplexer. It is possible that the transmission filter and the reception filter are two filters of a duplexer. However, it is also possible that the multiplexer is a multiplexer of a higher degree, e.g. a triplexer, a quadplexer, et cetera and the passband of the reception filter is directly or indirectly associated with the working frequency of the transmission filter.

Thus, it is possible to provide a multiplexer circuit with improved characteristics based on the idea that when a capacitance element at the output of a matching network is needed this capacitance element can be replaced with a capacitance element at the input of the filter and that this replacement capacitance element establishes then actually a notch in a frequency band, e.g. an RX frequency band.

It is possible that the reception filter comprises a capacitive element.

As stated above, especially at low frequencies large capacity values may be needed within the transmission signal path.

It is possible that the capacitive element of the reception filter notch circuit electrically connects the signal path, i.e. the transmission signal path, to ground.

Thus, it is possible that the capacitive element of the reception filter notch circuit establishes a shunt path to ground for frequency components that should not be submitted from the output port of the multiplexer circuit to the corresponding external circuit environment.

It is possible that the reception filter notch circuit is provided to create a notch in the transfer function S₂₁.

The matrix element S₂₁ of the transfer function denotes the amount of power at a given frequency submitted at the output port relative to the power received at the input port.

In this context a notch in the transfer function denotes a significant reduction of RF power located at a relatively narrow frequency range.

It is possible that the multiplexer is a duplexer. However, it is possible that the multiplexer is a multiplexer of a higher degree. In cases where the multiplexer is a duplexer the transmission filter and the reception filter establish the filters of the duplexer. In cases where the multiplexer is a multiplexer of a higher degree the multiplexer comprises at least one additional reception filter. In this case either the reception filter on the one side or the transmission filter on the other side can establish the filters of a duplexer.

The degree of the multiplexer is not limited. The multiplexer can be a multiplexer of a second degree (duplexer), of a third degree, of a fourth degree (quadplexer), et cetera.

It is possible that the reception filter notch circuit improves the reception cross isolation in a carrier aggregation system.

In such a configuration the reception filter is not directly associated with the transmission filter in such a way that the reception filter and the transmission filter form a duplexer. However, it is possible that the duplexer has an associated reception filter and the reception filter has an associated transmission filter and that a quadplexer is obtained. Correspondingly, the term “cross isolation” in a carrier aggregation system denotes that the isolation with respect to a reception filter frequency range of the respective “other” duplexer is improved.

The known term “carrier aggregation” denotes systems that can transmit and/or receive different transmission signals or different reception signals simultaneously.

Then it is preferred that the mentioned passband of the reception filter is the lower passband of the two reception filters.

It is possible that the multiplexer further comprises an impedance matching circuit between the input port and the transmission filter.

The impedance matching circuit is provided to match the relatively low output impedance of a power amplifier to an input impedance of the transmission filter. The impedance matching circuit can provide adaptive impedance matching. To that end the impedance matching circuit can comprise impedance elements of variable impedance. In particular capacitive elements with variable capacitances are preferred.

It is possible that the multiplexer further comprises a power amplifier connected to the input port. Additionally or as an alternative it is possible that the multiplexer has a low noise amplifier that is connected to the output port.

As mentioned earlier it is possible that the multiplexer is part of a frontend module. Thus, it is possible that a frontend module comprises a corresponding multiplexer, a power amplifier and optionally a low noise amplifier. The circuit elements of the multiplexer and the circuit elements of the power amplifier are combined in a single component.

As indicated earlier, Quadplexers or multiplexers of a higher degree are also possible. Further improvements can be made to reduce impedance variation according to the frequency dependence as much as possible. Then, variations in the transfer functions of the corresponding filters can be reduced. In particular with respect to reflections of power in signal paths that cause undesired ripple, the following is possible.

The impedance optimizations can be made with respect to a transmission filter so that the input impedance of the impedance matching circuit is as close as possible to the load light impedance, i.e. to the intrinsic impedance of the signal line. Thus, considering the specific properties of the signal line itself, it can lead to further optimizations of the filter's electrical properties. Compensation of variations of the signal line's frequency dependence, power dependence or amplifier gain dependence can be performed at the input side of the corresponding RF filter.

Further, the input side of the transmission filter can be provided such that its input impedance can be varied such that different gains caused by a frequency or power dependence of the circuit elements before the filter can be compensated. This can be obtained by making the filter impedance lie on a constant gain line (in a Smith chart) so that frequency variations do not alter the gain at the specific circuit node.

Another possibility to reduce passband ripple is to provide a small deviation from the circular line of a constant gain around a conjugated impedance to compensate for small errors in the filter transfer in the desired frequency band.

Filter structures can be optimized. An optimization of a filter structure can be to enhance the input impedance of the filter at those frequencies where the filter shows the greatest power dissipation.

A SAW filter (duplexer) has a maximum allowable power level for a cellular band. Defects in the duplexer usually occur with excessive power on the high side of the band generally in the smaller series elements. The maximum power depends strongly on the used power source and the duplexer impedances. It is proposed to deviate from a desired duplexer impedance to achieve a different maximum power in the total system. The input impedance should not be made at those frequency at which the respective filter receives too much power and exceeds the maximum power level.

In some saw filters (duplexer) it is desirable to suppress a band close to the TX band. According to an embodiment a proper setting of the filter input impedance is used to increase the suppression in a neighbored channel. The goal is to get more gain in the desired frequency band with the aid of the whole system and to get less gain for the undesirable frequency band. This can be done by intentionally producing a mismatch of the power amplifier PA with the PA-matching circuit at the frequency of the band to be suppressed. Thereby suppression of undesired bands can be maximized. In practice this means that the filter must be optimized for a given system. Enhancing the reflection S11 for the undesirable band can be set as a new goal of the filter optimization routine.

In a PAMiD module the total gain for harmonics is determined by input impedance of the filter and output impedance of the PA-matching circuit. According to an embodiment it is not a goal to reduce this gain, but to shift the maximum gain from an undesirable place to a place where it is not important. By an adjustment of the PA matching network, or of the TX input impedance gives a different frequency at which maximum gain occurs. So it is possible to shift the frequency of maximal gain to location where it does not matter and where neither a neighbor channel nor a harmonics occur. By doing this less gain is produced in these channels and suppression of same can be improved.

There are four ways proposed to shift this gain peak to a point where the damage is most limited.
1) The output impedance of the PA-matching can be pushed a little bit by choosing the internal impedance a little bit different.
2) The line length of the interconnect between PA or PA matching and filter rotate the output impedance of the PA-matching. Thereby the gain peak can be shifted
3) The input impedance of a filter at high frequencies is capacitive, which means that the dimensions of the first filter element determines the input impedance of the TX filter to a large extent. Hence, by varying the dimension of the first filter element (preferably a series element) input impedance can be varied.
4) The first element of a filter element may be a series or a shunt element. A choice of a proper kind of first filter element can be used to determine the input impedance of the TX filter to a large extent.

In practice, this means that all four possibilities of shifting need to be suitably selected and weighted to achieve a proper balance towards the desired goal.

In mobile communication systems like cellular communications a system consisting of a PA, PA-matching and TX filter (e.g., a SAW duplexer), the load line should be tuned for each frequency band to the correct impedance. For this purpose, parallel circuited capacities can be switched on or off. In a PAMiD fronted module in some places capacities are used while in other places too much capacity is already present. According to an embodiment a method is disclosed to also use these additional capacities to make more insolation in the RX band. The additional input capacity is replaced by an additional RX notch element with exactly the right capacity value in the TX band, then two problems have been solved. Instead of placing a capacity necessary for matching the power amplifier to the Tx filter in the matching circuit it is proposed to place the capacity at the input (towards PA) of the Tx filter parallel to the signal line. The capacitance value thereof can be selected to compensate for the frequency dependence of the matching circuit. At the same time, this capacitance can be used to produce an additional notch to improve the suppression for an unwanted frequency.

The notch has not to be limited to its own RX band. The notch can be used for any frequency. In a carrier aggregation solution, the notch can be used for RX cross isolation.

Central aspects of the present multiplexer and details of preferred embodiments are presented and further explained by the accompanying schematic figures.

In the figures:

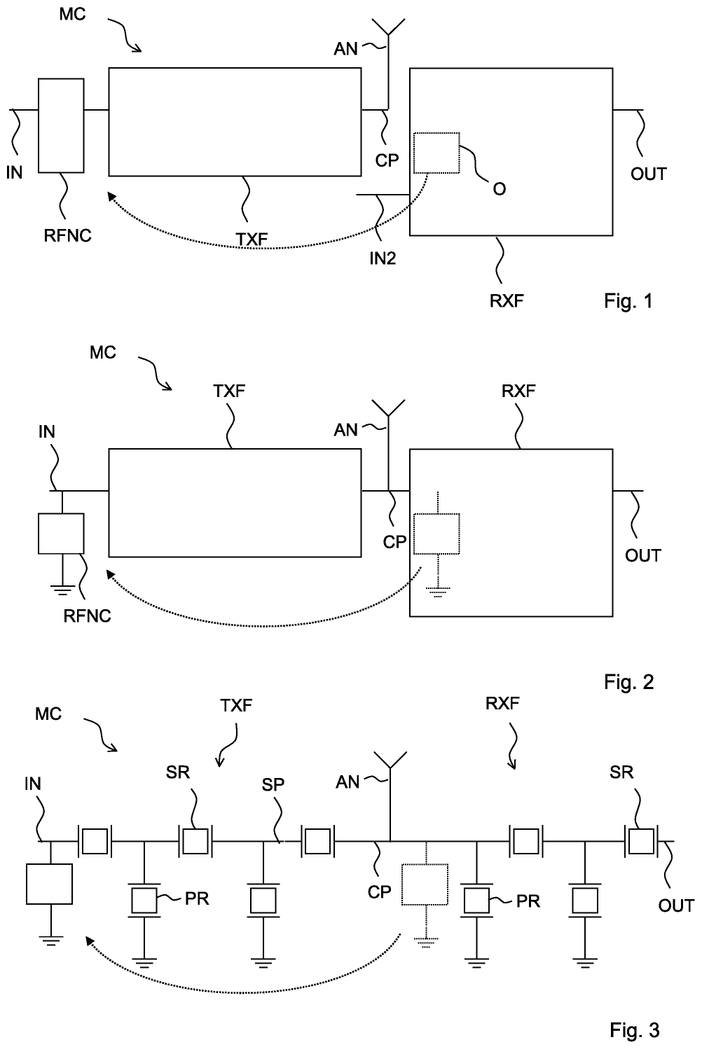

FIG. 1 illustrates the basic concept of the multiplexer.

FIG. 2 illustrates an example in the form of a duplexer.

FIG. 3 illustrates the use of a ladder-type-like configuration for transmission and reception filters.

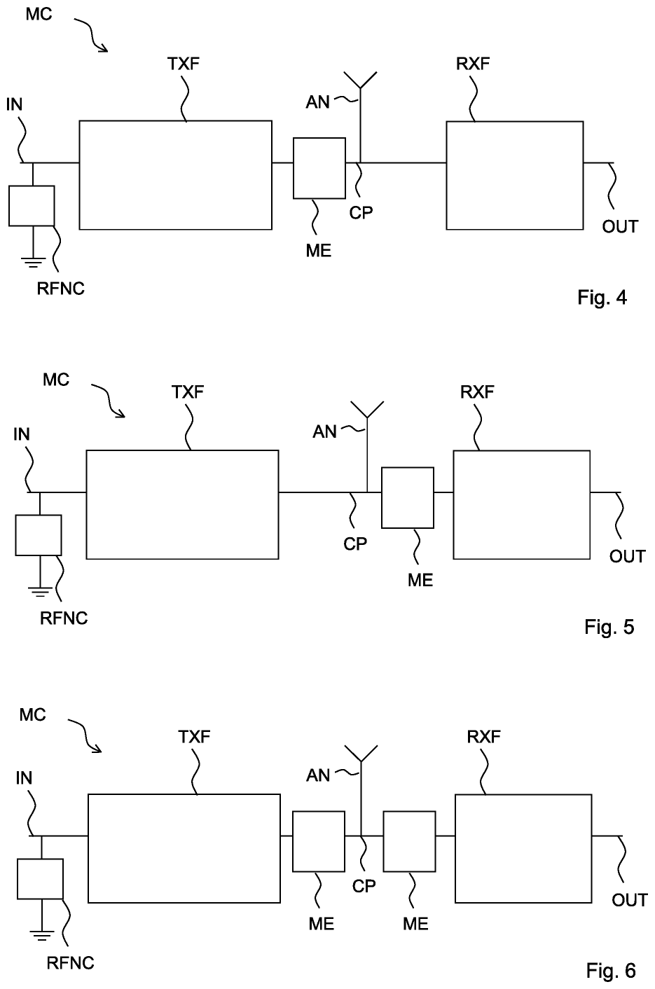

FIGS. 4 to 6 illustrate the possibility of further matching elements at the common port.

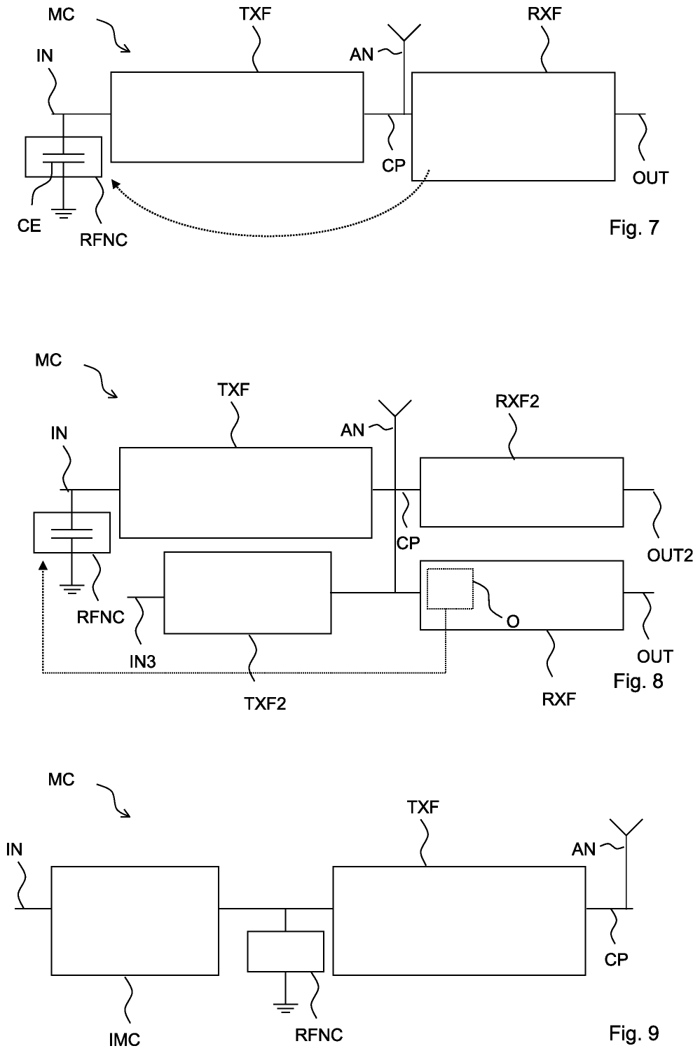

FIG. 7 illustrates the use of a capacitance element in the reception filter notch circuit.

FIG. 8 illustrates a quadplexer.

FIG. 9 illustrates the use of an impedance matching circuit.

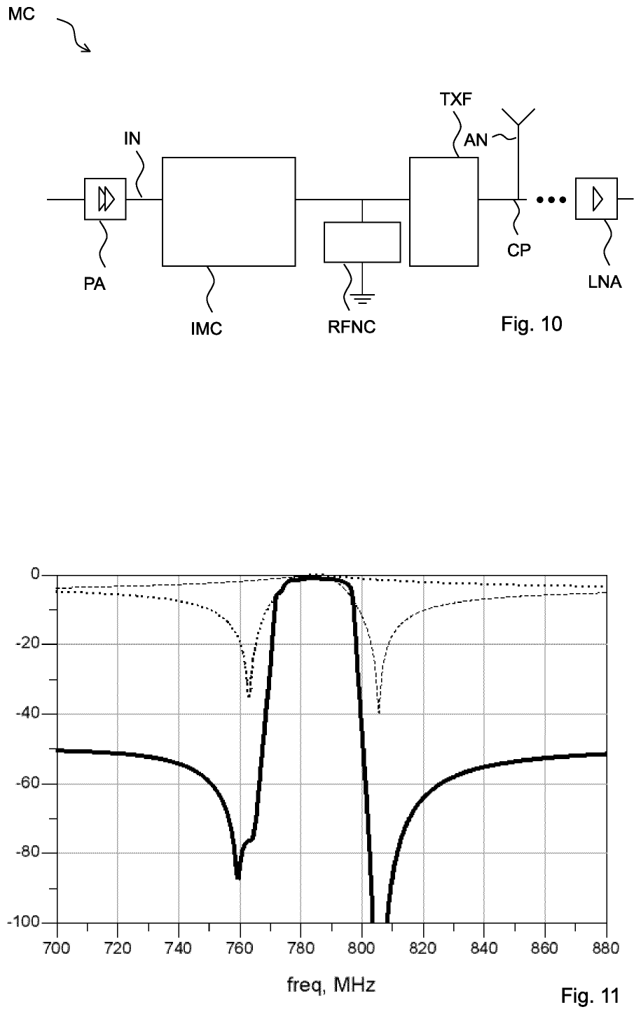

FIG. 10 illustrates the connection to power amplifier.

FIG. 11 illustrates the effects of a series element and a parallel element.

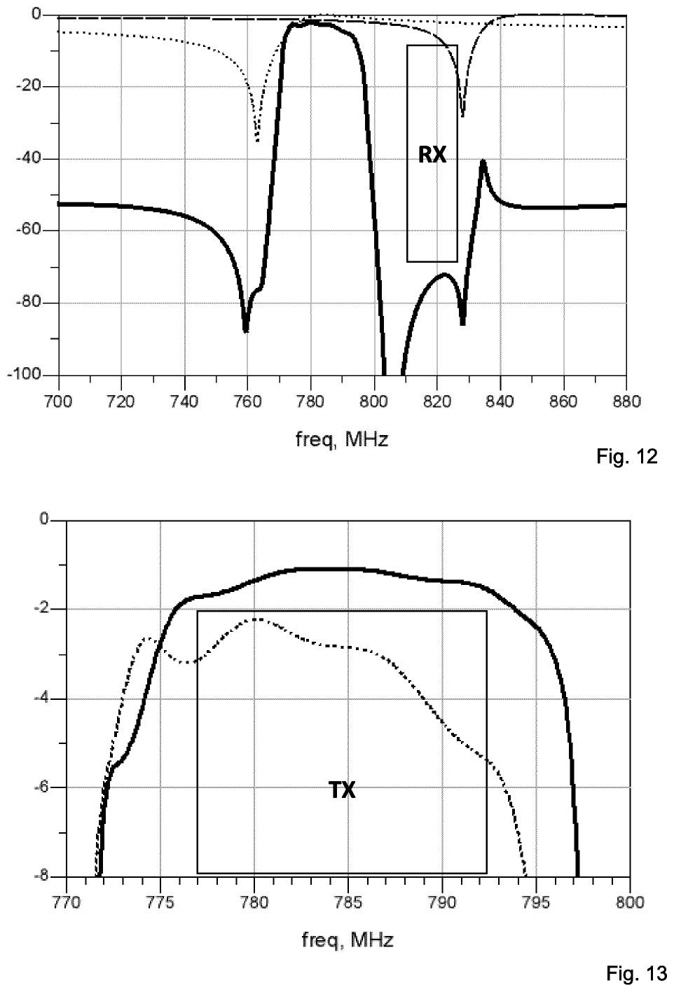

FIG. 12 illustrates the effect of an normal additional parallel element in enlarged view of the TX passband.

FIG. 13 illustrates an enlarged view of the passband frequencies with a normal additional parallel element.

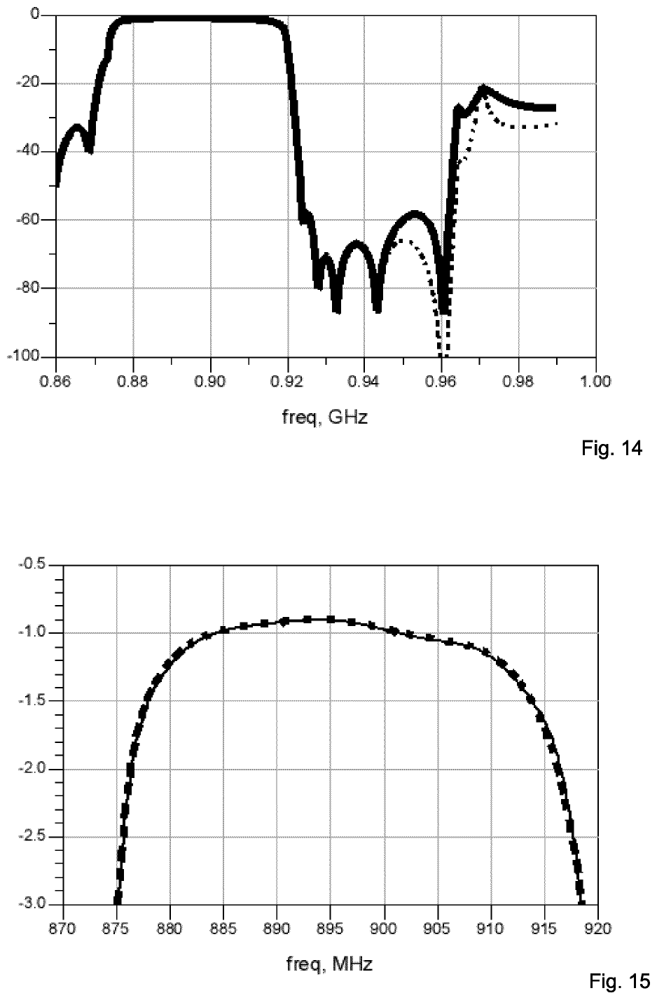

FIG. 14 illustrates transmission characteristics of a multiplexer as described above.

FIG. 15 illustrates an enlarged view of the passband frequencies.

FIG. 1 shows a basic configuration of the multiplexer circuit MC. The multiplexer circuit MC has an input port IN, a common port CP and an output port OUT. The input port IN is provided to receive RF signals that should be transmitted and that should be received from an external circuit environment. The output port OUT is provided to submit received RF signals to an external circuit environment of the corresponding mobile communication device. The common port CP is the port via which transmission signals are transmitted and reception signals are received. To that end the common port CP can be connected to an antenna AN, e.g. via an antenna port (not shown). A signal path electrically connects the input port IN to the common port CP. In the signal path a transmission filter TXF is connected. Between the input port IN and the transmission filter TXF the reception filter notch circuit RFNC is arranged. It was recognized that taking a corresponding circuit from a reception filter RXF and placing it before the transmission filter TXF allows maintaining a good isolation level while making handling the frequency dependencies in the transmission signal path easier. The translation of the corresponding circuit elements from the reception filter RXF to the transmission signal side keeps the total number of circuit elements constant and thus maintains compatibility with the trend towards miniaturization.

It is to be noted that the reception filter RXF does not necessarily have to be the reception filter that—in combination with the transmission filter TXF—establishes a duplexer. The reception filter RXF can be another reception filter of a multiplexer of a higher degree. Then the reception filter has its own input port IN2 via which reception signals are received.

By removing the corresponding circuit component from its origin O in the reception filter RXF, designing the reception filter RXF is simplified.

FIG. 2 illustrates the possibility of establishing a duplexer: The transmission filter TXF and the reception filter RXF establish the two RF filters of the multiplexer circuit MC, which is realized as a duplexer.

Further, it is possible that the reception filter notch circuit RFNC is arranged before the transmission filter TXF and electrically connected in a shunt path between the signal path connected to the input port IN on the one side and to ground on the other side.

FIG. 3 illustrates the possibility of utilizing a ladder-type-like structure for the transmission filter TXF and for the reception filter RXF. A ladder-type-like filter comprises series elements such as series resonators SR electrically connected in series in the signal path SP. In shunt paths between the signal path and ground parallel resonators PR are arranged.

Such a ladder-type-like configuration can be used to establish bandpass filters or band rejection filters. In the case of a transmission filter and of a reception filter the use of a bandpass filter is preferred.

However, the reception filter notch circuit can be realized as a band rejection filter having its own ladder-type-like configuration between the signal path SP and ground.

Series resonators and parallel resonators can be electroacoustic resonators working with acoustic waves. Resonators can be SAW resonators (SAW=surface acoustic wave), BAW resonators (BAW=bulk acoustic wave), GBAW resonators (GBAW=guided bulk acoustic wave) and/or TFSAW resonators (TF=thin film).

In electroacoustic resonators electrode structures combined with a piezoelectric material convert between RF signals and acoustic waves. Acoustic energy is confined to a resonator area utilizing acoustic mirror structures.

FIG. 4 illustrates the use of matching elements ME arranged between an output port of the transmission filter TXF and the common port CP. As an alternative (compare FIG. 5) it is possible to arrange matching elements ME between the common port and the input port of the reception filter RXF.

FIG. 6 illustrates the possibility of providing matching elements ME between the output port of the transmission filter TXF and the common port CP and between the common port CP and the input port of the reception filter RXF.

The matching elements shown in FIGS. 4 to 6 can be used to match the output impedance of the transmission filter for the corresponding frequency ranges to the input impedance of the reception filter. In particular, a high input impedance at the input port of the reception filter is wanted for transmission frequencies, while a desired specific impedance, e.g. 25 ohms, 5 ohms, 100 ohms or 200 ohms, is wanted at the input port of the reception filter for reception frequencies. Correspondingly, the impedance at the output port of the transmission filter should be an open circuit impedance for reception frequencies and an impedance matched to 25 ohms, 50 ohms, 100 ohms or 200 ohms for transmission frequencies.

This is obtained by choosing capacitance and inductance values of capacitance and inductance elements of the matching elements ME that lead to the needed electric decoupling of the filters.

FIG. 7 shows the possibility of using a capacitance element as an essential element of the reception filter notch circuit RFNC. The capacity of the capacitance element can be chosen such that the wanted notch in the corresponding frequency range of the corresponding reception signal path is obtained.

FIG. 8 shows the possibility of realizing the multiplexer circuit as a quadplexer. In addition to the transmission filter TXF and the reception filter RXF an additional transmission filter TXF2 and an additional reception filter RXF2 are provided. It is not necessarily the case that the origin of the circuit elements of the reception filter notch circuit RFNC is in the reception filter directly associated with a transmission filter TXF. In the configuration shown in FIG. 8 the origin O of the circuit elements of the reception filter notch circuit RFNC is from a reception filter RXF associated to the second transmission filter TXF2. In this configuration the reception filter notch circuit can be used for RX cross isolation, e.g. in a carrier aggregation system.

FIG. 9 illustrates the possibility of having an impedance matching circuit IMC between the input port and the transmission filter TXF, in particular between the input port IN and the reception filter notch circuit RFNC.

FIG. 10 illustrates the additional possibility of having the impedance matching circuit and/or the transmission filter receive RF signals from the power amplifier PA.

Additionally or as an alternative it is possible to provide a low noise amplifier LNA in a reception signal path.

FIG. 11 illustrates the relevance of shunt elements and series elements to establish a bandpass filter, e.g. in a ladder-type-like configuration. It is possible that a shunt element, e.g. a shunt resonator electrically connecting a signal path to ground, causes a notch at a lower frequency. A series element, e.g. a series resonator in a ladder-type-like configuration, causes a notch at a higher frequency. If the shunt element is combined with the series element in the ladder-type configuration, the combined effects of shunt and series elements create the shown transmission characteristic in the form of a passband.

When further frequency requirements are necessary, e.g. with the presence of a reception frequency band RX near a transmission frequency band, then additional measures are needed. In this case, an additional shunt element can be used to create an additional notch. In FIG. 12 (and in an enlarged view in FIG. 13) it is shown that isolation is improved. However, in the transmission frequency band an unwanted additional attenuation is obtained together with a passband ripple (the dashed line shows the effect of the additional notch element arranged at the reception side of a duplexer).

In contrast, FIGS. 14 and 15 (in an enlarged view) show transfer characteristics for the presented multiplexer circuit topology. It can be seen that in FIG. 14 the isolation is improved in the frequency range above the transmission frequency band while (compare FIG. 15) the shape of the transmission frequency band remains undisturbed.

The multiplexer circuit and the frontend module are not limited to the shown embodiments. Multiplexer circuits can comprise further circuit elements and/or further signal paths. Frontend modules can comprise further circuit components integrated therein.

### LIST OF REFERENCE SIGNS

AN: antenna
CE: capacitance element
CP: common port
IN: input port
IN2: input port of the reception filter RXF
IN3: third input port
LNA: low noise amplifier
MC: multiplexer circuit
ME: matching elements
O: origin of the circuit elements of the reception filter notch circuit
OUT: output port
OUT2: second output port
PA: power amplifier
PR: parallel resonator
RFNC: reception filter notch circuit
SR: series resonator
TXF: transmission filter

1. A multiplexer circuit comprising
an input port, a common port, an output port and a signal line between the input port and the common port,
a transmission filter between the input port and the common port,
a reception filter coupled to the output port,
a reception filter notch circuit coupled between the input port and the transmission filter, wherein
the reception filter has a passband and
the reception filter notch circuit is active at a frequency within the passband of the reception filter.

2. The multiplexer of claim 1, wherein the reception filter comprises a capacitive element.

3. The multiplexer of claim 2, wherein the capacitive element of the reception filter notch circuit electrically connects the signal line to ground.

4. The multiplexer of claim 1, wherein the reception filter notch circuit is provided to create a notch in the transfer function S21.

5. The multiplexer of claim 1, wherein
the multiplexer is a duplexer and the transmission filter and the reception filter are filters of the duplexer, or
the multiplexer is a multiplexer of a degree higher than 2, and the multiplexer comprises an additional reception filter.

6. The multiplexer of claim 1, wherein the reception filter notch circuit improves reception cross isolation in a carrier aggregation system.

7. The multiplexer of claim 1, further comprising an impedance matching circuit between the input port and the transmission filter.

8. The multiplexer of claim 1, further comprising
a power amplifier connected to the input port and the transmission filter and/or
a low noise amplifier connected to the output port.

9. A frontend module, comprising the multiplexer of claim 1 and a power amplifier, wherein the circuit elements of the multiplexer and the circuit elements of the power amplifier are combined in a single component.
